(19) United States
(12) Patent Application Publication
(10) Pub. No.: US 2015/0263012 A1
(43) Pub. Date: Sep. 17, 2015

(54) NONVOLATILE SEMICONDUCTOR MEMORY DEVICE AND MANUFACTURING METHOD THEREOF

(71) Applicant: Kabushiki Kaisha Toshiba, Minato-ku (JP)

(72) Inventor: Atsushi MURAKOSHI, Yokkaichi-shi (JP)

(73) Assignee: Kabushiki Kaisha Toshiba, Minato-ku (JP)

(21) Appl. No.: 14/294,303

(22) Filed: Jun. 3, 2014

Related U.S. Application Data
(60) Provisional application No. 61/950,877, filed on Mar. 11, 2014.

(51) Int. Cl. H01L 27/115; H01L 29/423; H01L 21/28; H01L 21/265; H01L 21/324; H01L 29/51; H01L 29/49

(52) U.S. Cl. CPC H01L 27/11521; H01L 29/511; H01L 29/42324; H01L 29/49; H01L 21/265; H01L 21/324; H01L 21/28273

(57) ABSTRACT

A nonvolatile semiconductor memory device comprises: a semiconductor layer; a gate insulating film formed on the semiconductor layer; a floating gate formed on the gate insulating film and including silicon as a material thereof; a charge accumulation film formed on a surface of the floating gate; a block insulating film formed on the charge accumulation film; and a control gate formed on the block insulating film. An upper layer of the floating gate includes germanium and boron.

### CROSS REFERENCE TO RELATED APPLICATIONS

This application is based on and claims the benefit of priority from prior U.S. Provisional Patent Application No. 61/950,877, filed on Mar. 11, 2014, the entire contents of which are incorporated herein by reference.

### FIELD

Embodiments described below relate to a nonvolatile semiconductor memory device and a manufacturing method thereof.

### BACKGROUND

In a nonvolatile semiconductor memory device, for example, a NAND type flash memory, there is a demand to increase an amount of charge that can be accumulated in a floating gate.

### BRIEF DESCRIPTION OF THE DRAWINGS

FIG. 1 shows an example of a schematic configuration of a memory cell array of a nonvolatile semiconductor memory device (NAND type flash memory) according to an embodiment.

FIG. 2 is a cross-sectional view taken along the line I-I of FIG. 1.

FIG. 3 is a cross-sectional view taken along the line II-II of FIG. 1.

FIG. 4 is a flowchart explaining a formation method of a Ge-segregated layer 14A.

FIGS. 5 and 6 respectively show write characteristics and erase characteristics of a floating gate 14 in which the Ge-segregated layer 14A is formed by steps of the present embodiment (FIG. 3).

FIG. 7 is an energy band diagram explaining advantages of forming the Ge-segregated layer 14A.

FIGS. 8A and 8B are graphs explaining advantages due to ion implantation of germanium.

FIGS. 9 and 10 are graphs explaining advantages of ion implantation of boron (B).

FIG. 11 shows a relationship between boron density and carrier density in the case of implanting boron ions without performing germanium ion implantation.

FIG. 12 shows a relationship between boron density and carrier density in the case of boron ion implantation after performing germanium ion implantation.

FIG. 13 is a graph showing a relationship between germanium dose and sheet resistance.

### DETAILED DESCRIPTION

A nonvolatile semiconductor memory device of an embodiment described below comprises: a semiconductor layer; agate insulating film formed on the semiconductor layer; a floating gate formed on the gate insulating film and including silicon as a material thereof; a charge accumulation film formed on a surface of the floating gate; a block insulating film formed on the charge accumulation film; and a control gate formed on the block insulating film. An upper layer of the floating gate includes germanium and boron.

Next, the nonvolatile semiconductor memory device according to the embodiment will be described in detail with reference to the drawings.

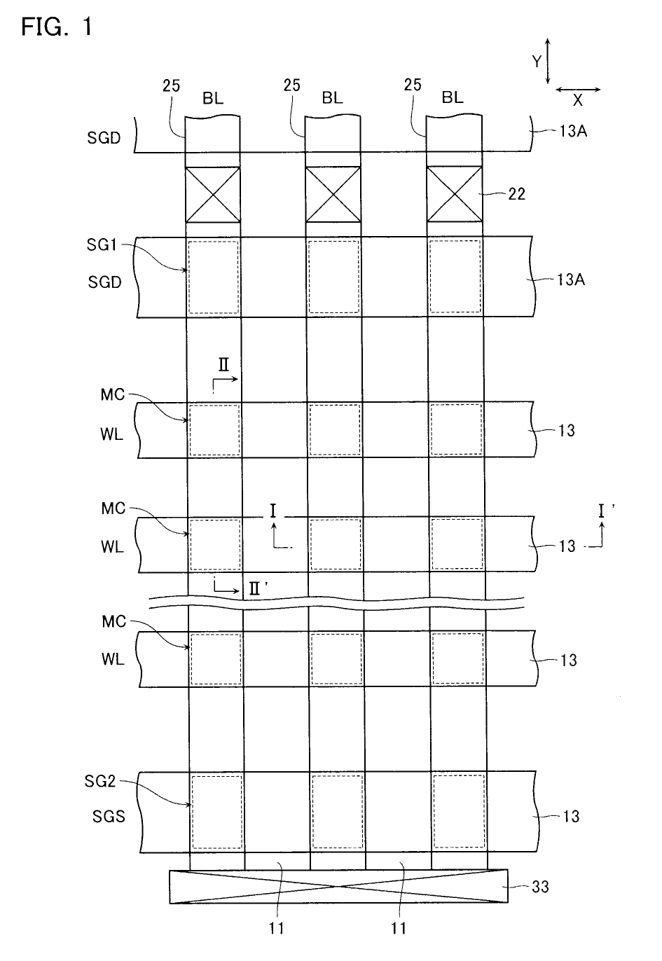

First, the nonvolatile semiconductor memory device according to the embodiment will be described with reference to FIG. 1, and so on.

[Schematic Configuration]

FIG. 1 shows an example of a schematic configuration of a memory cell array of the nonvolatile semiconductor memory device (NAND type flash memory) according to the embodiment. Word lines (WL) 13 and bit lines (BL) 25 are arranged intersecting each other, and a memory cell MC is formed at each of intersections of these word lines 13 and bit lines 25.

A plurality of the memory cells MC aligned in a bit line BL direction are connected in series by sharing between them source/drain diffusion layers as will be mentioned later. The plurality of memory cells MC connected in series configure one memory string. One end of the memory string is connected to the bit line BL via a drain side select gate transistor SG1. The bit line BL and the drain side select gate transistor SG1 are connected via a contact 22.

In addition, the other end of the memory string is connected to a source line SL not illustrated, via a source side select gate transistor SG2. The source line SL and the source side select gate transistor SG2 are connected via a source side contact 33.

A gate of the drain side select gate transistor SG1 is connected to a drain side select gate line (SGD) 13A arranged in parallel to the word line WL. In addition, a gate of the source side select gate transistor SG2 is connected to a source side select gate line (SGS) 13B arranged in parallel to the word line WL. Here, a direction in which the word line WL extends is defined as a word line direction (X direction), and a direction in which the bit line BL extends is defined as a bit line direction (Y direction).

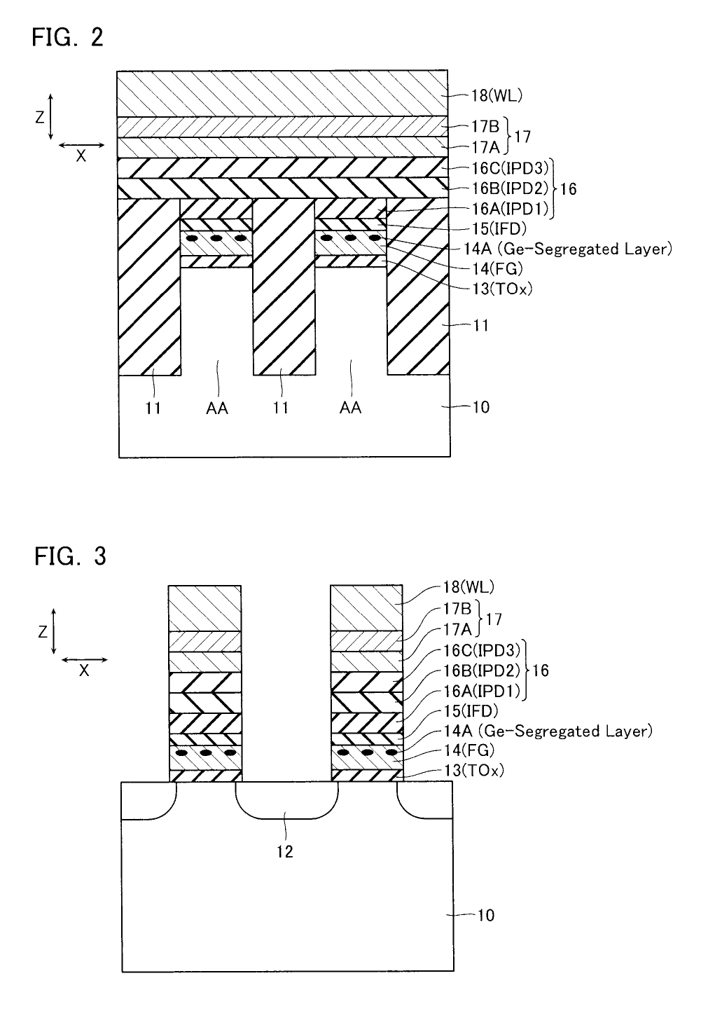

FIG. 2 is a cross-sectional view taken along the line I-I of FIG. 1. FIG. 3 is a cross-sectional view taken along the line II-II of FIG. 1.

As shown in FIG. 2, the memory cell MC is formed on a semiconductor substrate 10. Formed on a surface of this semiconductor substrate 10 with a certain spacing in the X direction are element isolation insulating films 11 that extend having the Y direction as a longer direction. The element isolation insulating film 11 is formed from, for example, silicon oxide (SiO2). A region of the semiconductor substrate 10 sandwiched by the element isolation insulating films 11 configures an active area AA where the memory string (memory cell) is formed. That is, the surface of the semiconductor substrate 10 is electrically isolated into a plurality of active areas AA by the element isolation insulating film 11. Similarly to the element isolation insulating films 11, the active areas AA extend having the Y direction as a longer direction, and are formed with a certain spacing in the X direction.

A plurality of the memory cells MC each comprise: a plurality of source/drain diffusion layers 12 disposed on the surface of the semiconductor substrate 10; agate insulating film 13 (tunnel insulating film) disposed on a channel region between these source/drain diffusion layers 12; and a floating gate 14 disposed on the gate insulating film 13. A film thickness of the gate insulating film 13 may be set to, for example, about 6 nm. Moreover, a film thickness of the floating gate 14 may be set to, for example, about 10 to 25 nm. This floating gate 14 includes in its upper layer a germanium (Ge)-segregated layer 14A into which Ge is implanted and in which a silicon density is lowered. This Ge-segregated layer 14A has boron (B) implanted therein in this region where the silicon density is lowered. This point will be described in detail later.

Note that in the case where a distance between the memory cells MC is small, it is also possible for the source/drain diffusion layer 12 to be omitted. This is because due to a so-called fringe effect, a conduction path penetrating the channel region of the plurality of memory cells MC can be generated even if there is no the source/drain diffusion layer 12.

Furthermore, this memory cell MC comprises a charge accumulation film 15 disposed on the floating gate 14. This charge accumulation film 15 has a function of accumulating a charge injected into the floating gate 14 via the gate insulating film 13 by a write operation, and is formed by, for example, silicon nitride (SiN). A film thickness of the charge accumulation film 15 may be set to, for example, about 2 nm. Existence of the charge accumulation film 15 makes it possible for an aspect ratio of the floating gate 14 to be reduced.

Formed on this charge accumulation film 15 is a block insulating film 16. As an example, this block insulating film 16 is configured by a first insulating film 16A formed from hafnium oxide (HfOx), a second insulating film 16B formed from silicon oxide (SiO2), and a third insulating film 16C formed from hafnium oxide (HfOx).

Deposited on this block insulating film 16 via a barrier metal 17 is a conductive film 18 acting as the word line WL. As an example, film thicknesses of the first insulating film 16A, the second insulating film 16B, and the third insulating film 16C may each be set to about 5 nm. In this example illustrated in FIG. 2, a CMP method is executed in the first insulating film 16A. Due to this, the first insulating film 16A has an upper surface with a height in the Z direction substantially matched to that of an upper surface of the element isolation insulating film 11. The first insulating film 16A is provided only between the element isolation insulating films 11. Moreover, the second insulating film 16B and the third insulating film 16C are formed on the flattened upper surfaces of the first insulating film 16A and the element isolation insulating film 11, with a striped shape having the X direction as a longer direction similarly to the word line WL.

As an example, the barrier metal 17 includes a first metal film 17A formed from tantalum nitride (TaN) and a second metal film 17B formed from tungsten nitride (WN). Film thicknesses of the first metal film 17A and the second metal film 17B may each be set to about 5 nm. In addition, the conductive film 18 is formed by a metal such as tungsten (W).

Note that the block insulating film 16, although it has a three-layer structure in the illustrated example, is not limited to this structure, and the block insulating film 16 may also be configured as a single-layer structure formed by a single material. Moreover, there may also exist a boundary layer between the charge accumulation film 15 and the block insulating film 16 and between the block insulating film 16 and the barrier metal 17.

Note that although omitted from illustration, patterning of the bit line (BL) is executed by depositing the conductive film 18 which is to be the word line WL and forming a film of a mask material thereon, and then processing the gate insulating film 13 through conductive film 18 to the semiconductor substrate 10 with a width of approximately 20 nm by photolithography and etching. Moreover, the source/drain diffusion layer 12 is formed by performing ion implantation of an n type impurity (phosphorus (P), and so on) in a self-aligning manner using the gate electrode formed in this way as a mask, and then diffusing the impurity by heat processing of 955° C. for 30 seconds.

The memory cell shown in FIGS. 2 and 3 has a so-called flat cell structure in which the upper surface of the element isolation insulating film 11 is at a higher position than the surface of the floating gate 14. However, this is only an example, and technology of this embodiment may be applied also to a structure in which the upper surface of the element isolation insulating film 11 is at a lower position than the surface of the floating gate 14 (also called a rocket cell structure). Moreover, similar technology can be applied also to a memory cell array having the memory cells arranged three-dimensionally.

[Formation Method of Ge-Segregated Layer 14A]

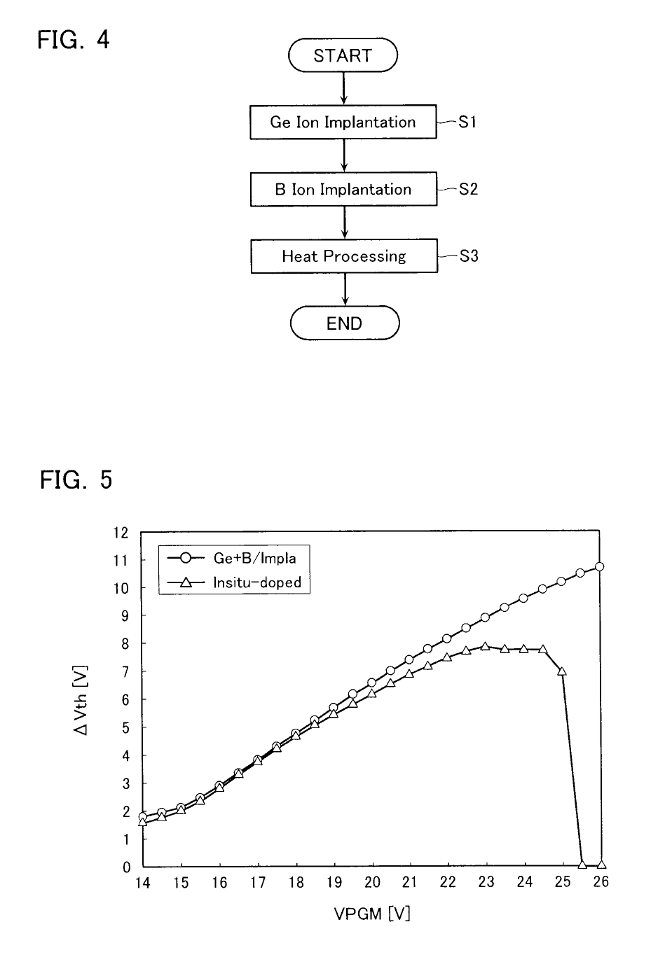

A formation method of the previously mentioned Ge-segregated layer 14A will now be described with reference to the flowchart of FIG. 4.

After forming a polysilicon film which is to be the floating gate 14, a surface of that polysilicon film undergoes ion implantation of germanium (Ge) with, for example, the implanted dose of 2.5×10¹⁵ cm⁻² at the acceleration energy of 0.5 keV (step S1). In this step S1, a depth of a position where concentration of germanium ions becomes the maximum concentration depth (Rp) is approximately 2.5 nm. Note that the Rp is a depth from the surface of the floating gate 14. Moreover, a spreading width ΔRp of 1σ of the maximum concentration depth (Rp) is approximately 1.2 nm. Due to such a step, the germanium is distributed at a depth of within several nm from the surface of the floating gate 14.

Furthermore, density of germanium at the maximum concentration depth in this step S1 is approximately 7×10²¹ cm⁻³, and is a density exceeding 10 percent of silicon density (approximately 5×10²² cm⁻³). Due to this ion implantation of germanium whose atomic radius is larger than that of silicon, excessive knock-on of silicon atoms occurs in a vicinity of the maximum concentration depth (Rp) from the surface of the polysilicon film. This knock-on causes a condition where silicon density lowers extremely.

Next, after completion of step S1, a region where germanium ions have been implanted is further implanted with boron (B) (step S2). As an example, the ion implantation of boron (B) is performed with the dose of 5×10¹⁴ cm⁻² at the acceleration energy of 0.2 keV. By so doing, the boron (B) can be implanted at high concentration into the above-mentioned region where silicon density has lowered. Furthermore, the boron (B) formed here is clustered (B₁₂ cluster), and can be stably maintained due to the existence of the germanium.

In this step S2, a depth of a position where concentration of boron (B) becomes Rp′ (maximum concentration depth) is approximately 1.7 nm. Note that Rp′ is a depth from the surface of the floating gate 14. This depth substantially matches a position of the region formed by the germanium ion implantation where Si density has lowered. Furthermore, a maximum concentration of boron (B) is approximately 2×10²¹ cm⁻³, and sufficiently fulfills a density required for formation of metallic boron (B₁₂ cluster).

After the ion implantation of boron, heat processing is performed at the temperature of 600° C., for the heating time of 1 hour, in nitrogen ambient atmosphere (step S3), and a step for recovering a damaged region caused by boron ion implantation is executed. Due to the above, formation of the Ge-segregated layer 14A is completed.

[Write Characteristics and Erase Characteristics of Memory Cell of Present Embodiment]

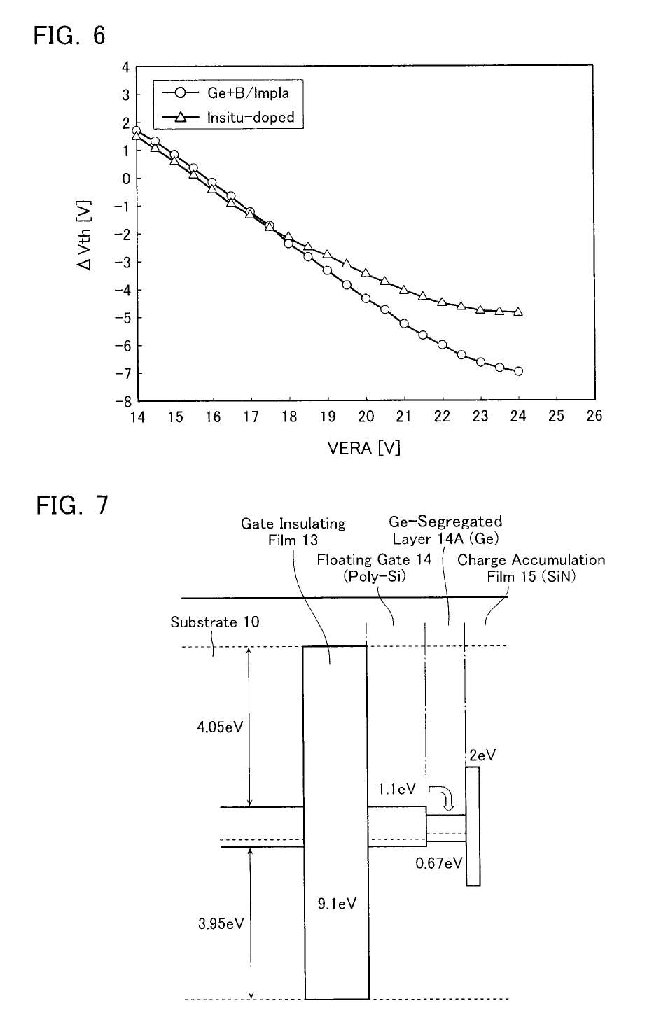

FIGS. 5 and 6 respectively show write characteristics and erase characteristics of the floating gate 14 in which the Ge-segregated layer 14A is formed by steps of the present embodiment (FIG. 3) (round dotted curves). The horizontal axes respectively denote a write voltage (VPGM) and an erase voltage (VERA) applied to a selected word line during a write operation and an erase operation, and the vertical axes denote amounts of change ΔVth in threshold voltage of the memory cell obtained by the write operation and the erase operation. Also shown for comparison are graphs of the cases where in-situ doping is performed at a concentration of 1×10²¹ cm⁻³ adding only boron (B) without Ge implantation into the floating gate (polysilicon film) (triangular dotted curves).

In the case of the floating gate 14 in which the Ge-segregated layer 14A is formed according to the steps of FIG. 3, write and erase characteristics are both found to be significantly improved over those of a floating gate 14 of a comparative example. It is understood from this result that the present embodiment makes it possible to obtain a memory cell in which charge accumulation efficiency is high, moreover in which the erase operation also may be easily performed.

Next, advantages of forming this Ge-segregated layer 14A will be described with reference to the energy band diagram of FIG. 7. The energy gap of polysilicon which is the material of the floating gate 14 is approximately 1.1 eV, but the energy gap of germanium in the Ge-segregated layer 14A is approximately 0.67 eV, which is narrower than that of polysilicon, and a difference in electronic barrier height occurs. As a result, it becomes easier for electrons that have flowed through a conduction band of the polysilicon to flow into an electronic reservoir included in the germanium. Furthermore, a super-saturation activation layer due to the B₁₂ cluster is formed in the Ge-Segregated layer 14A. This is thought to cause a charge accumulation capacitance of the floating gate 14 to increase.

[Advantages of Germanium Ion Implantation]

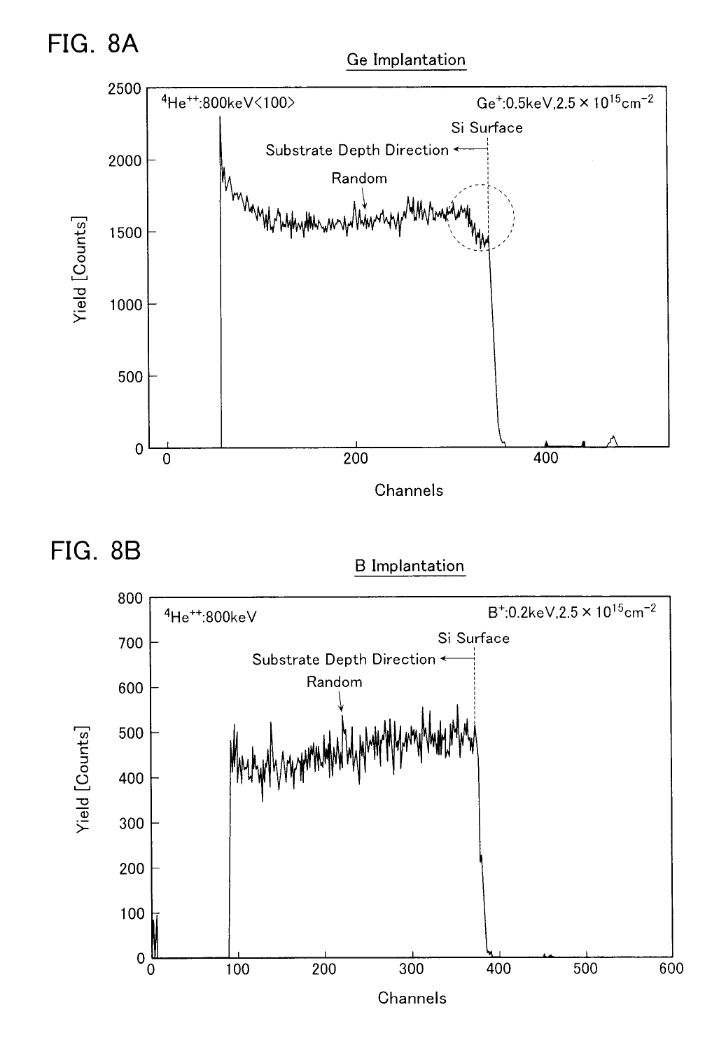

Next, advantages due to ion implantation of germanium will be described with reference to FIGS. 8A and 8B. Ion implantation of high dose germanium leads to occurrence of a lowering of silicon density from the surface of the floating gate 14 (polysilicon film) to a vicinity of the maximum concentration depth (Rp). This is demonstrated from RBS (Rutherford Backscattering Spectrometry) channeling spectra shown in FIGS. 8A and 8B. In order to make it easier to understand this lowering of silicon density, FIGS. 8A and 8B show RBS channeling spectrums when ion implantation is performed with the polysilicon film having its film thickened to 30 nm. In FIGS. 8A and 8B, the horizontal axes show a channel number indicating depth from the surface of the polysilicon film, and the vertical axes show scattering intensity of helium ions.

In FIG. 8A, ion implantation of germanium is performedunder identical conditions to in the embodiment (acceleration energy 0.5 keV, implanted dose 2.5×10¹⁵ cm⁻²). As shown by the dotted circle in FIG. 8A, a random spectrum and significant lowering of silicon density is observed from a surface layer of the polysilicon film to a depth expected as being close to the depth Rp.

On the other hand, FIG. 8B shows the case where ion implantation of only boron (B) whose atomic radius is smaller than that of germanium is performed at the implanted dose of 2.5×10¹⁵ cm⁻² similarly to in the case of germanium. A random spectrum lowering in the surface layer of the polysilicon film is not observed. This result indicates that by performing high concentration ion implantation of germanium (Ge) whose atomic radius is large, a state is achieved in the surface layer of the polysilicon film that knock-on of silicon atoms occurs excessively and silicon density lowers extremely. Moreover, as will be mentioned later, by having germanium implanted in the silicon, it becomes easier for the B₁₂ cluster which is clustered boron to be formed in a stable state in a vicinity of germanium whose lattice constant is larger than that of silicon.

[Advantages of Implantation of Boron (B)]

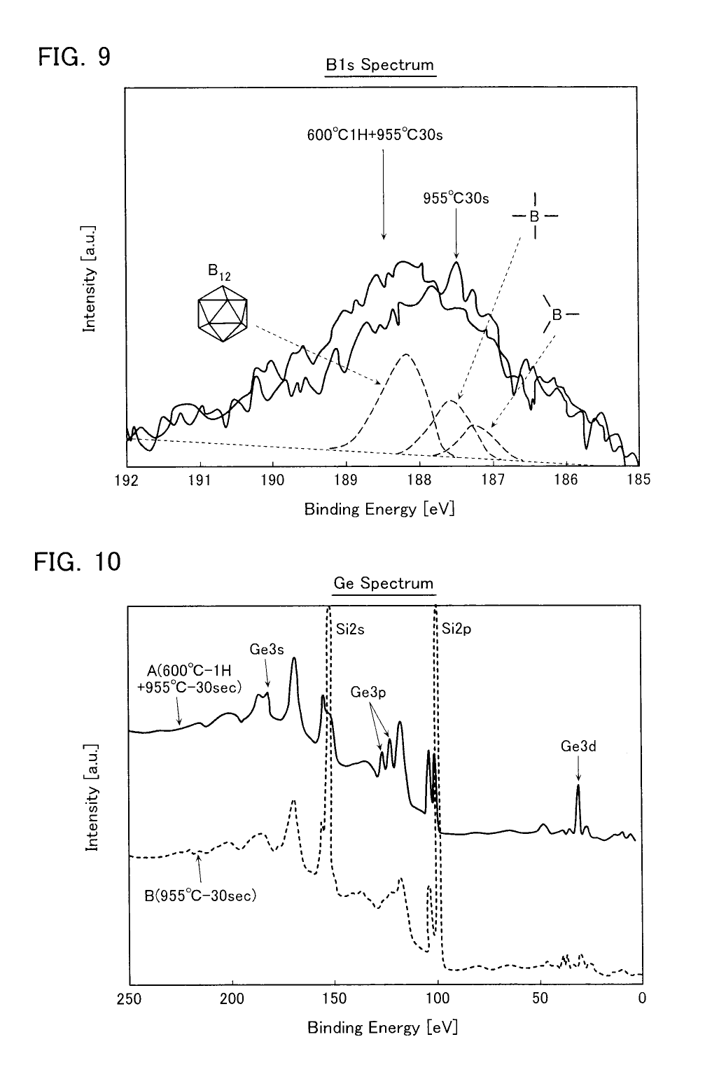

Next, advantages of ion implantation of boron (B) will be described with reference to FIGS. 9 and 10. As a result of performing high concentration ion implantation of boron (B) into the polysilicon that forms the floating gate 14, density of boron (B) reaches a density of 8×10²⁰ cm⁻³ or more in the vicinity of the maximum concentration depth (Rp). Then, the B₁₂ cluster is formed in a self-aligning manner due to thermal energy of the ion implantation. This B₁₂ cluster provides a divalent electron deficiency state in a icosahedral structure.

Therefore, it is made possible to generate carrier density greater than or equal to the density of solid-solubility limit without performing heat processing.

However, the B₁₂ cluster in the silicon is decomposed with increasing temperature of the heat processing temperature and increasing time, and its concentration eventually returns to the density of solid-solubility limit in the silicon. In order to enable the B₁₂ cluster to exist stably in the silicon, restriction of thermal-budget is required, and application to a device is difficult.

FIG. 9 is the peak resolution of B is spectrum diagram showing a segregation state of boron. As shown in FIG. 9, when, as in the above-mentioned embodiment, after ion implantation of germanium and boron, heat processing is performed for example at the high temperature and for the short time of 955° C. and 30 seconds, a maximum peak of the B is spectrum of boron appears in a vicinity of a binding energy of 187.6 eV. Usually, 3-coordinate boron has a peak of spectrum at the binding energy of 187.2 eV, 4-coordinate boron has a peak at the binding energy of 187.7 eV, and 5-coordinate boron has a peak in the vicinity of the binding energy of 188.1 eV. Usually, 3-coordinate boron shows an inactive state at an interstitial position, and 4-coordinate boron generates a carrier due to substitution by, for example, Si. Moreover, 5-coordinate boron derives from binding energy of the B₁₂ cluster. FIG. 9 shows that when, after high-density ion implantation of germanium and boron, heat processing is performed for example at a high temperature and for a short time of 955° C. and 30 seconds, 4-coordinate boron becomes dominant, and almost all of the boron exists in the silicon in an inactive state.

On the other hand, when a first heat processing is executed at a low temperature and for a long time of 600° C. and 1 hour and then a second heat processing is performed at a high temperature and for a short time of 955° C. and 30 seconds, then, contrary to when only heat processing at a high temperature and for a short time is performed, a peak of the B is spectrum of boron appears in a vicinity of a binding energy of 188.1 eV. This means that when a low-temperature long-time heat processing is once performed and then a high-temperature short-time heat processing is performed, 5-coordinate boron (that is, the B₁₂ cluster) can be formed to exist stably. This change is due to the Ge-segregated layer 14A in the surface layer of the floating gate 14. The temperature of the first heat processing is not strictly limited to 600° C., and as an example may be set in the range of 525° C. to 600° C.

FIG. 10 shows a wide energy range spectrum of germanium including 3s orbit (Ge 3s). A graph of the case where heat processing is performed at a low temperature and for a long time of 600° C. and 1 hour and then heat processing is performed at a high temperature and for a short time of 955° C. and 30 seconds is shown by curve A. The intensity of 3d orbit (Ge 3d) spectra of germanium is found to indicate a high value. This shows that the concentration of germanium is high. Furthermore, the spectrums of 3s orbit (Ge 3s) and 3p orbit (Ge 3p) of germanium that show Ge—Ge bonds and Ge—B (cluster B) bonds are clearly observed. Performing low-temperature long-time heat processing and high-temperature short-time heat processing in this way enables concentration of germanium in the surface of the floating gate 14 to be increased.

On the other hand, a graph of the case where only high-temperature short-time heat processing is performed without low-temperature long-time heat processing being performed is shown by curve B in the graph of FIG. 10. In each of Ge 3s, Ge 3p, and Ge 3d, spectrum intensity is observed remarkably low. Moreover, the spectra of 2p orbit of silicon is observed to be shifted to the high-energy side. This shows that the silicon-germanium (SiGe) bonds are formed in the vicinity of the surface of the floating gate 14.

These results show that performing heat processing at a low temperature and for a long time of 600° C. and 1 hour and then performing heat processing at a high temperature and for a short time of 955° C. and 30 seconds results in formation of the Ge-segregated layer 14A having germanium segregation in the surface of the polysilicon of the floating gate 14. These results also show that by having the B₁₂ cluster incorporated into the Ge-segregated layer 14A, a thermally stable binding state is maintained. This is thought to be due to silicon atoms being excessively knocked-on by high-concentration germanium ion implantation, and silicon atom density lowering near the surface. In the low-temperature heat processing at 600° C., solid phase growth from the amorphous layer formed by ion implantation proceeds, but its diffusion coefficient is small. Hence, the state of lowered density of silicon atoms in the surface layer of the polysilicon layer is maintained, and Ge—Ge binding becomes dominant.

On the other hand, in the high-temperature heat processing at 955° C., it is thought that the diffusion coefficient also increases, hence diffusion of Si atoms proceeds and lattice strain is relaxed, and a change to SiGe binding proceeds.

Regarding binding of boron in germanium, the atomic radius of germanium is 0.122 nm, whereas the atomic radius of boron is 0.088 nm, which is 30 percent smaller than that of germanium.

By substituting germanium with boron, a strain occurs owing to the lattice contracts. Therefore, by having crystal recovery performed by an heat processing, boron whose atomic radius is small is thought to be clustered, thereby being incorporated into a lattice position and crystal strain relaxes. The size of a B₁₂ cluster is 0.522 nm, which is different from the size of 0.566 nm of tetrahedral structure configured from five germanium atoms by approximately 8%. Therefore, it is thought that stable existence can be more easily achieved by clustered boron rather than substituting by monoatomic boron whose atomic radius is small.

A B₁₂ cluster with a icosahedral structure consisting of 12-boron atoms, by being substituted for a 4-coordinate crystal lattice of silicon or germanium, provides a divalent electron-deficiency state. Therefore, carriers are generated at a ratio (carrier generation ratio) of 2/12=1/6 to the boron density. The carrier generation ratio is smaller than that of monoatomic boron, but the density of solid-solubility limit is large, hence a high carrier concentration can be obtained.

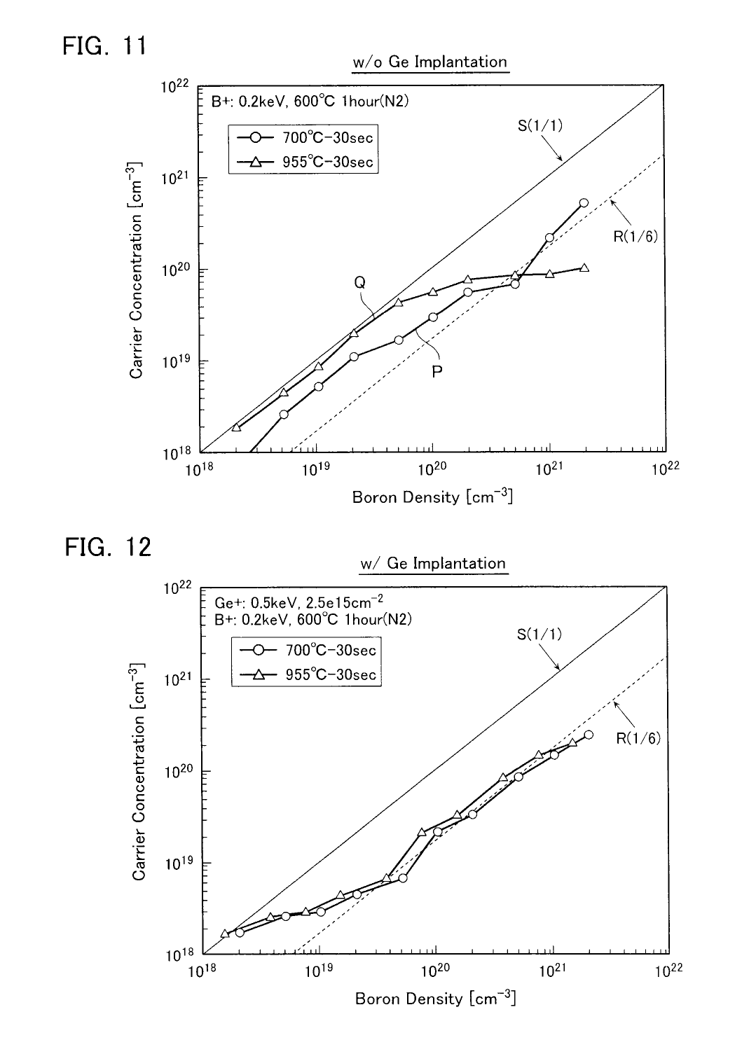

FIG. 11 shows a relationship between boron density and carrier density in the case of boron-ion implantation without performing germanium ion implantation. This graph shows the case where density of boron is changed setting implanted dose of ion implantation of boron between from 1×10¹³ cm⁻² to 1×10¹⁶ cm⁻². In addition, this graph exemplifies the case where, after ion implantation of boron carried out as mentioned above, heat processing at 600° C. for 1 hour is performed, and heat processing at 700° C. or 955° C. for 30 seconds is further performed.

Moreover, in conjunction with the above, the graph of FIG. 11 also displays a hypothetical graph (broken line R) of the case of a carrier generation ratio of 1/6, that is, of the case where the B₁₂ cluster is formed, and a hypothetical graph (solid line S) of the case of a carrier generation rate of 1/1, that is of the case where ordinary three-coordinate boron is formed.

The graph of the case where boron is implanted without performing germanium ion implantation and then heat processing at 700° C. for 30 seconds is performed is shown by curve P in FIG. 11. This case shows that since carrier generation ratio is approximately 1/6 at the density of boron of approximately 8×10²⁰ cm⁻³ or more, the B₁₂ cluster is formed in this concentration region.

Moreover, the graph of the case where boron is implanted without performing germanium ion implantation and then heat processing at 955° C. for 30 seconds is performed is shown by curve Q in FIG. 11. In this case, dissolution of the B₁₂ cluster proceeds and inert boron becomes dominant, whereby carrier generation rate ends up being lower than 1/6.

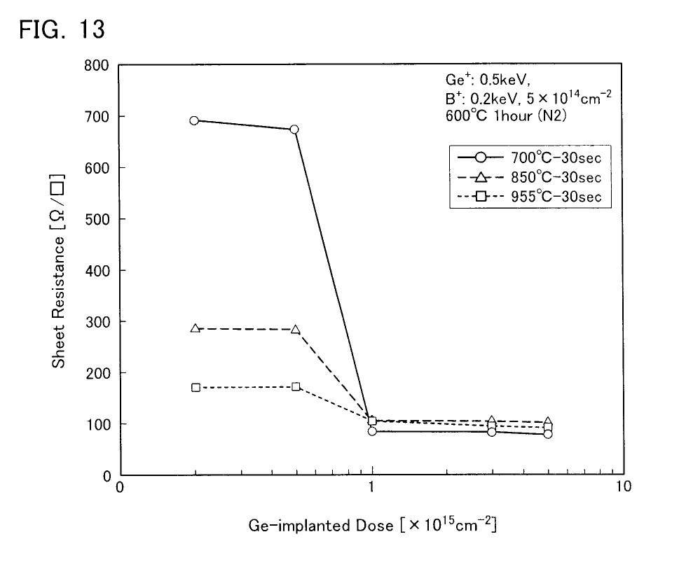

On the other hand, FIG. 12 shows the relationship between boron density and carrier density in the case of implantation of boron after performing germanium ion implantation. In the case that germanium ion implantation is performed, it is found that carrier generation ratio is larger than 1/6 even at a low boron density such as, for example, approximately 3×10¹⁹ cm⁻³. Moreover, heat processing temperature dependency is not observed, either. Also, the B₁₂ cluster is formed stably. This is thought to be caused by density of solid-solubility limit in silicon and germanium. The density of solid solubility limit of germanium at the heating temperature of 800° C. is lower than that of silicon. Thus, the former is approximately 1×10¹⁹ cm⁻³, whereas the latter is approximately 3×10¹⁹ cm⁻³.

Therefore, considering that boron existing at or above the density of solid-solubility limit is easily clustered, a generation ratio of the B₁₂ cluster is thought to be higher in germanium. Although the B₁₂ cluster has a low activation ratio, i.e., at 1/6, 1/6 of carriers can be generated with respect to the boron density. Due to this, a super-saturation activation layer of boron over the density of solid solubility limit, i.e., 2×10²⁰ cm⁻³ can be formed stably in silicon. This is what FIG. 12 shows. Moreover, it is known that diffusion of boron in germanium hardly occurs, contrary to boron in silicon. It is therefore thought that by boron dissolving in a region where germanium is segregated, it becomes more difficult for dissolution of the B₁₂ cluster to occur.

In the region where silicon atoms are knock-on excessively due to high concentration germanium ion implantation to cause silicon-atom density to be lowered in a vicinity of the surface and germanium to be segregated (the Ge-segregated layer 14A), the ion implantation dose of germanium is important.

FIG. 13 is a graph showing a relationship between germanium ion implantation dose and sheet resistance. Here, the germanium implantation dose is changed between from 2×10¹⁴ cm⁻² to 5×10¹⁵ cm⁻². Ion implantation of boron is further performed at the acceleration energy of 0.2 keV and implanted dose of 5×10¹⁴ cm⁻². Then, low-temperature long-time heat processing at 600° C. for 1 hour is performed and high-temperature short-time heat processing at 700° C. to 955° C. for 30 seconds is further performed. After that, sheet resistance is measured. When ion implantation dose of germanium is 1×10¹⁵ cm⁻² or less, heating temperature dependency of sheet resistance is observed. As the heating temperature rises, the sheet resistance decreases. This is thought to be the effect of carrier generation due to binding with monoatomic boron due to formation of SiGe.

On the other hand, at the germanium implantation dose of 1×10¹⁵ cm⁻² or more, heat-processing temperature dependency of sheet resistance is found to be hardly observed. Germanium density at the maximum concentration depth at this implantation dose is approximately 5×10²¹ cm⁻². It may be estimated from this result that the density of germanium with which segregation of germanium is formed due to generation of the excessive knock-on silicon region and low-temperature heat processing is 5×10²¹ cm⁻³. Thus, it is thought that by performing ion implantation of germanium of the density of 5×10²¹ cm⁻³ or more, the stable B₁₂ cluster is formed due to segregation of germanium due to generation of the excessive knock-on silicon region and low-temperature heat processing is formed. In other words, it is thought that by performing ion implantation of germanium of approximately 10% or more in density with respect to density of silicon according to the lattice constant thereof, the stable B₁₂ cluster is formed due to segregation of germanium due to generation of the excessive knock-on silicon region and low-temperature heat processing is formed.

[Other]

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device, comprising:
a semiconductor layer;
a gate insulating film formed on the semiconductor layer;
a floating gate formed on the gate insulating film and including silicon as a material thereof;
a charge accumulation film formed on a surface of the floating gate;
a block insulating film formed on the charge accumulation film;
a control gate formed on the block insulating film; and
an upper layer of the floating gate including germanium and boron.

2. The nonvolatile semiconductor memory device according to claim 1, wherein
density of silicon in the upper layer of the floating gate lowers randomly the more closely the surface is approached.

3. The nonvolatile semiconductor memory device according to claim 1, wherein
the boron includes clustered boron.

4. The nonvolatile semiconductor memory device according to claim 3, wherein
density of silicon in the upper layer of the floating gate lowers randomly the more closely the surface is approached.

5. The nonvolatile semiconductor memory device according to claim 1, further comprising an element isolation insulating film that isolates the semiconductor layer into a plurality of active areas,
wherein a surface of the element isolation insulating film is at a higher position than the surface of the floating gate.

6. The nonvolatile semiconductor memory device according to claim 5, wherein
the boron includes clustered boron.

7. The nonvolatile semiconductor memory device according to claim 6, wherein
density of silicon in the upper layer of the floating gate lowers randomly the more closely the surface is approached.

8. The nonvolatile semiconductor memory device according to claim 1, wherein
the upper layer of the floating gate includes germanium of a density of 5×10²¹ cm⁻³ or more.

9. The nonvolatile semiconductor memory device according to claim 8, wherein
the boron includes clustered boron.

10. The nonvolatile semiconductor memory device according to claim 9, wherein
density of silicon in the upper layer of the floating gate lowers randomly the more closely the surface is approached.

11. The nonvolatile semiconductor memory device according to claim 1, wherein
the upper layer of the floating gate includes boron of a density of 8×10²⁰ cm⁻³ or more.

12. The nonvolatile semiconductor memory device according to claim 11, wherein
the boron includes clustered boron.

13. The nonvolatile semiconductor memory device according to claim 11, wherein
density of silicon in the upper layer of the floating gate lowers randomly the more closely the surface is approached.

14. The nonvolatile semiconductor memory device according to claim 1, wherein
the g upper layer of the floating gate includes germanium of a density of 5×10²¹ cm⁻³ or more and includes boron of a density of 8×10²⁰ cm⁻³ or more.

15. The nonvolatile semiconductor memory device according to claim 14, wherein
the boron includes clustered boron.

16. The nonvolatile semiconductor memory device according to claim 15, wherein
density of silicon in the upper layer of the floating gate lowers randomly the more closely the surface is approached.

17. The nonvolatile semiconductor memory device according to claim 15, wherein in the upper layer of the floating gate includes germanium in a segregated manner.

18. A manufacturing method of a nonvolatile semiconductor memory device, the nonvolatile semiconductor memory device comprising a gate insulating film formed on a semiconductor layer, a floating gate formed on the gate insulating film and including silicon as a material thereof, a charge accumulation film formed on a surface of the floating gate, a block insulating film formed on the charge accumulation film, and a control gate formed on the block insulating film, the method comprising:
performing ion implantation of germanium into the surface of the floating gate;
after the ion implantation of the germanium, performing ion implantation of boron into the surface of the floating gate; and
performing heat processing on the floating gate.

19. The manufacturing method according to claim 18, wherein
the heat processing includes a first heat processing at a first temperature and a second heat processing at a second temperature larger than the first temperature.
